(19) United States
(12) Patent Application Publication
(10) Pub. No.: US 2010/0258826 A1
(43) Pub. Date: Oct. 14, 2010

(54) LIGHT EMITTING DIODE AND METHOD FOR MANUFACTURING THE SAME

(75) Inventor: Ryouichi Takeuchi, Chichibu-shi (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K.K., Minato-ku, Tokyo (JP)

(21) Appl. No.: 12/747,282

(22) PCT Filed: Nov. 25, 2008
(86) PCT No.: PCT/JP2008/071296

§ 371 Date: Jun. 10, 2010

(30) Foreign Application Priority Data
Dec. 12, 2007 (JP) 2007-320645

(51) Int. Cl. H01L 33/30; H01L 33/36; H01L 33/62

(52) U.S. Cl. 257/94; 438/47; 257/99; 257/E33.023; 257/E33.005; 257/E33.065; 257/E33.066

(57) ABSTRACT

A light emitting diode (1) of the invention is provided with: a light emitting section (3) which includes a light emitting layer (2); a substrate (5) that is joined to the light emitting section (3) via a semiconductor layer (4); a first electrode (6) on an upper surface of the light emitting section (3); a second electrode (7) on a bottom surface of the substrate (5); and an ohmic electrode (8) around an outer perimeter of the light emitting section (3) on the semiconductor layer (4), and in the outer perimeter of the light emitting section (3), the ohmic electrode (8) and the substrate (5) are conductive, and a penetrating electrode (9) is provided in the semiconductor layer (4), passing through the semiconductor layer (4) in a thickness direction. Thus, it is provided a light emitting diode with high brightness in which the current flowing in the light emitting layer is uniform, and the light emission efficiency from the light emitting layer is high.

### TECHNICAL FIELD

The present invention relates to a light emitting diode and a method for manufacturing the same.

Priority is claimed on Japanese Patent Application No. 2007-320645, filed Dec. 12, 2007, the content of which is incorporated herein by reference.

### BACKGROUND ART

Heretofore, as a light emitting diode (abbreviation: LED) that emits visible red, orange, yellow, or yellow-green radiation, a compound semiconductor LED having a light emitting layer comprising for example phosphide aluminum gallium indium (composition formula (Al_{X}Ga_{1-X})_{Y}In_{1-Y}P; 0≦X≦1, 0<Y≦1) is known. In such an LED, a light emitting section having a light emitting layer comprising (Al_{X}Ga_{1-X})_{Y}In_{1-Y}P; (0≦X≦1, 0<Y≦1) is formed on a substrate material such as gallium arsenide (GaAs) or the like, which is generally optically opaque with respect to light emitted from the light emitting layer, and is not so mechanically strong.

Therefore, recently, in order to obtain a visible light LED with higher luminance, or for the purpose of further improving the mechanical strength of components, a technique has been disclosed in which the substrate material that is opaque to the emitted light is removed, and afterwards, a support layer (substrate) that transmits or reflects the emitted light, and that is a material having an excellent mechanical strength, is newly joined in order to form an joining-type LED (for example, refer to Patent Documents 1 to 5).

On the other hand, in order to obtain a visible light LED with high luminance, a method is used for improving the light emission efficiency through the device constitution. In a device structure in which electrodes are formed on the front face and the rear face of a semiconductor light emitting diode, a technique for achieving high luminance through the shape of the side face of the device has been disclosed (for example, refer to Patent Document 6).

Furthermore, Patent Document 7 discloses a light emitting device in which ohmic metal is embedded in an organic adhesive layer in which a metal layer and a reflecting layer are bonded.

[Patent Document 1] Japanese Patent (Granted) Publication No. 3230638

[Patent Document 2] Japanese Unexamined Patent Application, First Publication No. H06-302857

[Patent Document 3] Japanese Unexamined Patent Application, First Publication No. 2002-246640

[Patent Document 4] Japanese Patent (Granted) Publication No. 2588849

[Patent Document 5] Japanese Unexamined Patent Application, First Publication No. 2001-57441

[Patent Document 6] U.S. Pat. (Granted) Publication No. 6,229,160

[Patent Document 7] Japanese Unexamined Patent Application, First Publication No. 2005-236303

### DISCLOSURE OF INVENTION

### Problems to be Solved by the Invention

However, in a structure in which current flows from the top to bottom of a light emitting diode (vertical direction with respect to the light emitting layer), in the case where an ohmic electrode is formed at a joining interface, the joining surface becomes uneven, so that there is a problem in that it is difficult to join.

In the case where the ohmic electrode is not formed at the joining interface, in order to reduce the electrical resistance on the joining surface, not only is an advanced joining technique required, but also the impurity concentration and the material of the joining interface are restricted, so that solutions to light absorption, mechanical stress, and the like, are necessary. Furthermore, since it is difficult to make the electrical resistance at the joining interface uniform, there is also a problem regarding the uniformity of current flowing to the light emitting layer.

Moreover, in the case where the light emitting layer is square, if the light emitted from the inside of the light emitting layer strikes a side face diagonally, it is likely to be reflected against the inside, so that there is a problem regarding the light emission efficiency of the side face.

The present invention has been made in view of the above circumstances, and has an object of providing a light emitting diode with high luminance in which stable joining can be formed easily, the current flowing in a light emitting layer is uniform, and the light emission efficiency from the light emitting layer is high.

### Means for Solving the Problem

In order to solve the above problems, a light emitting diode of the present invention is characterized in that there are provided: a light emitting section which includes a light emitting layer; a substrate that is joined to the light emitting section via a semiconductor layer; a first electrode on an upper surface of the light emitting section; a second electrode on a bottom surface of the substrate; and an ohmic electrode around an outer perimeter of the light emitting section on the semiconductor layer, and in the outer perimeter of the light emitting section, the ohmic electrode and the substrate are conductive, and a penetrating electrode is provided in the semiconductor layer, passing through the semiconductor layer in a thickness direction.

Furthermore, in the light emitting diode of the present invention, a planar shape of the light emitting layer is circular, with consideration to the arrangement of the penetrating electrode and light emission efficiency.

Moreover, the configuration of the light emitting diode of the present invention is such that the ohmic electrode surrounds the outer perimeter of the light emitting section.

Furthermore, in the light emitting diode of the present invention, the planar shapes of the light emitting section and the first electrode, and the planar shape of the ohmic electrode are similar, and a distance between the outer perimeter of the light emitting section and the ohmic electrode is constant.

Moreover, in the light emitting diode of the present invention, the light emitting section is provided with cladding layers made from semiconductor material on a top and bottom of the light emitting layer.

Furthermore, in the light emitting diode of the present invention, the semiconductor layer has at least a layer made from GaP.

Moreover, in the light emitting diode of the present invention, the light emitting layer contains at least AlGaInP.

Furthermore, in the light emitting diode of the present invention, the substrate is a transparent substrate made from any one of GaP, AlGaAs, and SiC.

Moreover, in the light emitting diode of the present invention, the substrate is a metal substrate containing at least any one of Al, Ag, Cu, and Au, or is made from a Si substrate having a reflective film formed with any one of Al, Ag, Cu, Au, and Pt.

Furthermore, in the light emitting diode of the present invention, the first electrode has an ohmic electrode, a transparent conductive film layer, and a pedestal electrode.

A method for manufacturing a light emitting diode of the present invention includes: a step for forming a laminated structure of epitaxial layers by stacking at least a contact layer, a first cladding layer, a light emitting layer, a second cladding layer, and a semiconductor layer, in order on a substrate for laminating epitaxial layers, a step for adhering a substrate on the semiconductor layer side of the light emitting section; a step for removing the substrate for laminating epitaxial layers from the laminated structure of epitaxial layers to form a light emitting section; a step for providing a penetrating electrode in the semiconductor layer, passing through the semiconductor layer in a thickness direction, in an outer perimeter of the light emitting layer; a step for providing an ohmic electrode which is joined to the penetrating electrode, on the semiconductor layer, in an outer perimeter of the light emitting layer; and a step for providing a first electrode on an upper surface of the light emitting section and a second electrode on a bottom surface of the substrate.

Moreover, the method for manufacturing a light emitting diode of the present invention produces a light emitting diode according to any one of those described above.

### EFFECTS OF THE INVENTION

A light emitting diode of the present invention is provided with: a light emitting section which includes a light emitting layer; a substrate that is joined to the light emitting section via a semiconductor layer; a first electrode on an upper surface of the light emitting section; a second electrode on a bottom surface of the substrate; and an ohmic electrode around an outer perimeter of the light emitting section on the semiconductor layer, and in the outer perimeter of the light emitting section, the ohmic electrode and the substrate are conductive, and a penetrating electrode is provided in the semiconductor layer, passing through the semiconductor layer in the thickness direction. As a result, current flowing from the second electrode can flow to the light emitting section via the substrate, the penetrating electrode, and the ohmic electrode. Furthermore, since the ohmic electrode is not at the interface of the substrate and the semiconductor layer, the adhesive interface is not uneven, which makes the structure easy to join. Moreover, the electrical resistance of the adhesive interface need not necessarily be a low resistance, so restrictions associated with the adhesive method, the condition, and the quality and material of the adhesive substrate are reduced, so that stable adhesion is possible.

Furthermore, since the planar shape of the light emitting layer is circular, reflection of the light from the inside of the light emitting layer against the side face of the light emitting layer is reduced, so that not only is the light emission efficiency increased, but also light is emitted from the side face uniformly.

Moreover, since the planar shape of the ohmic electrode is a shape surrounding the outer perimeter of the light emitting section, current easily flows to the first electrode uniformly, and emission also becomes uniform.

Furthermore, since profiles of the planar shape of the light emitting section and the first electrode, and the planar shape of the ohmic electrode, are similar, and the distance between the outer perimeter of the light emitting section and the ohmic electrode is constant, current flows easily to the light emitting section more uniformly, and emission also becomes more uniform. Moreover, since the planar shape of the first electrode is circular, and the electrode has no corners, so that the electrostatic withstanding resistance improves. Therefore, if the planar shape of the light emitting section and the first electrode, and the planar shape of the ohmic electrode, are both circular, current flows most uniformly, the whole light emitting layer can be used efficiently, and emission also becomes uniform, increasing the luminance.

Furthermore, since the light emitting section has a cladding layer on the top and bottom of the light emitting layer, the carriers that cause radiative recombination can be confined in the light emitting layer, so that high light emitting efficiency can be obtained.

Moreover, since the semiconductor layer is transparent against emitted light, high luminance can be obtained.

Furthermore, since the semiconductor layer has a layer made from at least GaP, it can obtain good ohmic contact with the ohmic electrode, so that the operating voltage can be reduced.

Moreover, since the light emitting layer contains at least AlGaInP with good light emitting efficiency, it is possible to obtain yellow-green to red visible light emitting diodes with high light emission efficiency.

Furthermore, since the substrate is a transparent substrate made from any one of GaP, AlGaAs, and SiC, it is possible to obtain high luminance, and furthermore, depending on the material of the substrate, it is also possible to improve the heat dissipation and mechanical strength.

Moreover, since the substrate is a metal substrate containing at least any one of Al, Ag, Cu, and Au, or an Si substrate with a reflective film formed with any one of Al, Ag, Cu, and Pt, there are advantages in that if it is made from metal, its thermal conductivity is good, and if it is made from Si, it is easy to process and inexpensive.

Furthermore, since the first electrode has an ohmic electrode, a transparent conductive film layer, and a pedestal electrode, it is possible to make the pedestal electrode small, and to reduce the absorption of light by selecting a material with a high reflection rate for the pedestal electrode. Moreover, by providing a uniform ohmic electrode, it is possible to increase the light emission efficiency of the light emitting diode.

The method for manufacturing a light emitting diode of the present invention includes: a step for forming an epitaxial laminated layer structure by stacking at least a contact layer, a first cladding layer, a light emitting layer, a second cladding layer, and a semiconductor layer, in order on a substrate for laminating epitaxial layers; a step for adhering a substrate on the semiconductor layer side of the light emitting section; a step for removing the substrate for laminating epitaxial layers from the laminated structure of epitaxial layers to form a light emitting section; a step for providing a penetrating electrode in the semiconductor layer, passing through the semiconductor layer in a thickness direction, around the outer perimeter of the light emitting layer; a step for providing an ohmic electrode, which is joined to the penetrating electrode, on the semiconductor layer, around an outer perimeter of the light emitting layer; and a step for providing a first electrode on an upper surface of the light emitting section and a second electrode on a bottom surface of the substrate. As a result, current flowing from the second electrode to the substrate can flow to the light emitting section via the penetrating electrode and the ohmic electrode. Furthermore, by providing the ohmic electrode not at the adhesive interface of the substrate and the semiconductor layer but on the upper surface of the semiconductor layer, the adhesive interface does not become uneven, which makes the structure easy to join.

### BRIEF DESCRIPTION OF THE DRAWINGS

FIG. 1A is a plan view of a light emitting diode according to a first embodiment of the present invention.

FIG. 1B is a cross-sectional diagram along line A-A′ of the light emitting diode shown in FIG. 1A.

FIG. 2A is a plan view of a light emitting layer whose shape is a nearly circular polygon, among application examples of the light emitting diode according to the first embodiment of the present invention.

FIG. 2B is a plan view of another light emitting layer whose shape is a nearly circular polygon, among application examples of the light emitting diode according to the first embodiment of the present invention.

FIG. 3A is a plan view of a light emitting section that is surrounded by curved lines, among application examples of the light emitting diode according to the first embodiment of the present invention.

FIG. 3B is a plan view of a light emitting section that is surrounded by an ellipse, among application examples of the light emitting diode according to the first embodiment of the present invention.

FIG. 4 is a cross-sectional diagram of an epitaxial laminated layer structure according to the first embodiment of the present invention.

FIG. 5 is a cross-sectional diagram of a light emitting diode lamp according to the first embodiment of the present invention.

FIG. 6A is a plan view of a light emitting diode according to a second embodiment of the present invention.

FIG. 6B is a cross-sectional diagram along line B-B′ of the light emitting diode shown in FIG. 6A.

### BRIEF DESCRIPTION OF THE REFERENCE SYMBOLS

1, 1A, 1B, 1C, 1D, 1E Light Emitting Diode
2, 2A Light Emitting Layer
3, 3A, 3B, 3C, 3D, 3E Light Emitting Section
4, 4A, 4B, 4C, 4D, 4E Semiconductor Layer
5, 5A Substrate
6, 6A, 6B, 6C, 6D, 6E First Electrode
7, 7A Second Electrode
8, 8A Ohmic Electrode
9, 9A, 9B, 9C, 9D, 9E Penetrating Electrode
10a, 10b, 10A, 10B Cladding Layer
11 Substrate for Laminating Epitaxial Layers
12 Epitaxial Growth Layer
12a Buffer Layer
12b Contact Layer
13 Epitaxial Laminated Layer Structure
14 LED Lamp
15 Mounting Substrate
16 n Electrode Terminal
17 Gold Wire
18 Epoxy Resin
6a Pedestal Electrode
6b Transparent Conductive Film Layer
6c Ohmic Electrode

### BEST MODE FOR CARRYING OUT THE INVENTION

Hereunder is a detailed description of a light emitting diode of the present invention and a method of manufacturing the same with reference to the drawings.

### First Embodiment

### Light Emitting Diode

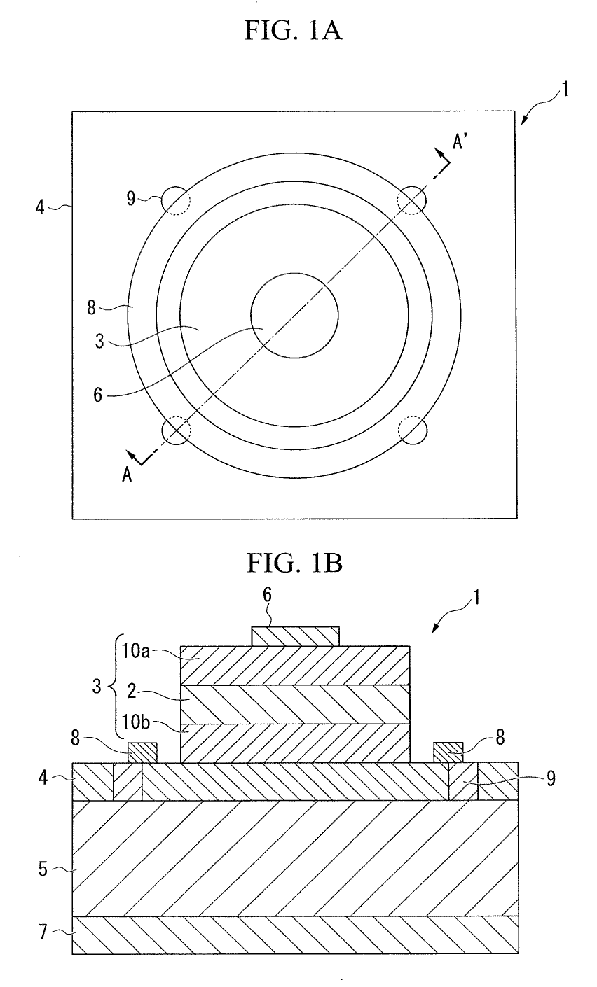

As shown in FIGS. 1A and 1B, a light emitting diode (LED) according to a first embodiment of the present invention is characterized in that there are provided: a light emitting section 3 which includes a light emitting layer 2; a substrate 5 bonded to the light emitting section 3 via a semiconductor layer 4; a first electrode 6 on an upper surface of the light emitting section 3; a second electrode 7 on a bottom surface of the substrate 5; and an ohmic electrode 8 around an outer perimeter of the light emitting section 3 on the semiconductor layer 4, and in the outer perimeter of the light emitting section 3, the ohmic electrode 8 and the substrate 5 are conductive, and penetrating electrodes 9 are provided in the semiconductor layer 4, passing through the semiconductor layer 4 in the thickness direction.

The light emitting section 3 is a compound semiconductor laminated structure having a pn joint including the light emitting layer 2, and the light emitting layer 2 can be formed from a compound semiconductor of either an n type or p type conduction type. The present invention is ideally suited to a light emitting diode in which a light emitting section is formed from a thin material, and a substrate for laminating epitaxial layers which absorbs light from the light emitting layer. The light emitting layer is expressed by the general expression (AlₓGa₁₋ₓ)_{y}In_{1-y}P (0≦X≦1, 0<Y≦1). A GaN type material is also effective for use as a light emitting layer with a thin light emitting section.

The light emitting section 3 may be any structure from double hetero, single quantum well (abbreviation: SQW), and multi quantum well (abbreviation: MQW). However, in order to obtain emission with excellent monochromaticity, the MQW structure is preferable. The composition of (AlₓGa₁₋ₓ)_{y}In_{1-y}P (0≦X≦1, 0<Y≦1) which forms a barrier layer forming a quantum well (abbreviation: QW) structure, and a well layer is determined such that a desired emission wavelength results.

Furthermore, intermediate layers may be provided between the light emitting layer 2 and the cladding layers 10a and 10b, for changing the band discontinuity between the layers gradually. In this case, it is ideal that the intermediate layers are formed from a semiconductor material that has a band gap in the middle of the light emitting layer 2 and the cladding layers 10a and 10b.

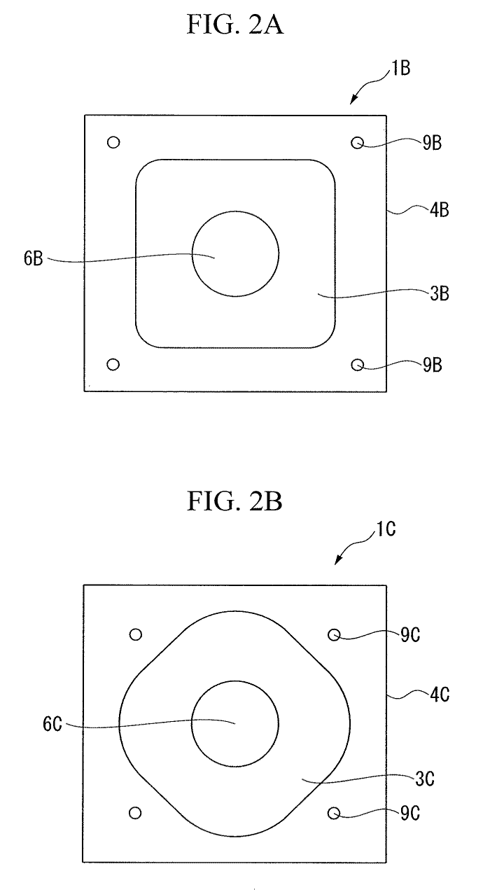

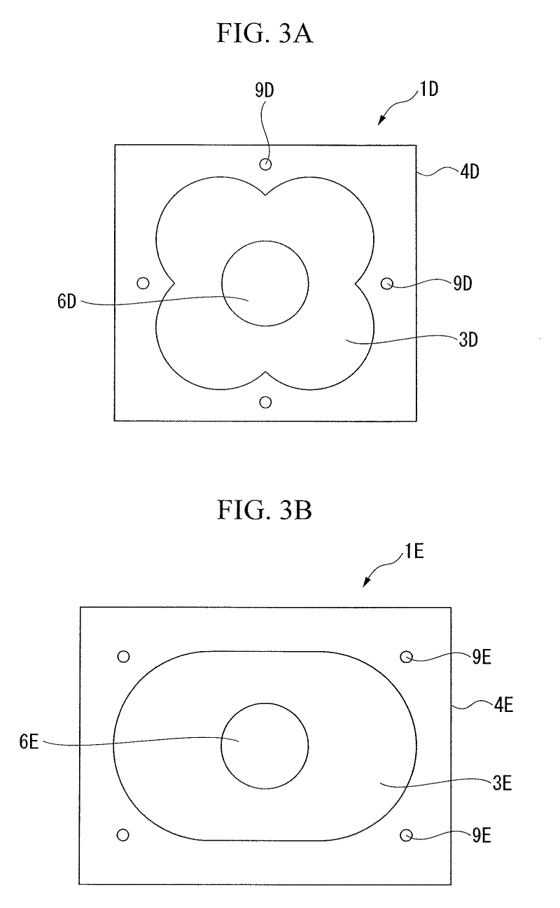

It is especially preferable that the shapes of the light emitting section 3 and the light emitting layer 2 are circular. Alternatively, they may be for example, nearly circular polygons as shown in FIGS. 2A and 2B, a shape surrounded by curved lines as shown in FIG. 3A, or elliptical as shown in FIG. 3B. With squares and rectangles, if light emitted from the inside of the light emitting layer 2 strikes the side face of the light emitting layer 2 diagonally, it is likely to be reflected toward the inside, the light emission efficiency is reduced, and the luminance of the light emitting diode 1 is reduced.

However, if the shapes of the light emitting section 3 and the light emitting layer 2 are circular, the light emitted from the inside of the light emitting layer 2 is unlikely to be reflected against the side face of the light emitting layer 2, so that the light emission efficiency is increased.

In the present invention, it is preferable that the semiconductor layer 4 is transparent for high bgightness. A transparent substrate can be formed from a III-V group compound semiconductor crystal such as gallium phosphide (GaP), aluminum gallium arsenide (AlGaAs), and gallium nitride (GaN), a II-VI group compound semiconductor crystal such as zinc sulphide (ZnS), and zinc selenide (ZnSe), or a IV group semiconductor crystal such as hexagonal or cubic silicon carbide (SiC).

In the present invention, it is preferable that the substrate 5 that is joined to the light emitting section 3 via the semiconductor layer 4 is formed from a metal substrate that contains at least any one of Cu, Au, Al, and Ag, or a Si substrate on which a reflective film is formed from Al, Ag, Cu, Pt, or the like. In the case where the substrate 5 is formed from a metal substrate, since the thermal conductivity is good, and Al and Ag have high reflectance against all wavelengths, and Cu has high reflectance against red colors, it is more preferable. Furthermore, in the case where the substrate 5 is formed from Si, there are advantages in that it is easy to process and inexpensive.

In the present invention, when the maximum width of the main light emission surface (outline of the light emitting section 3) is 0.8 mm or greater, the effect is large. The maximum width means the widest part of the outline of the surface. For example, in the case of a circle, it is the diameter, and in the case of a rectangle and a square, the diagonal is the maximum width. It is necessary for a light emitting diode for use at high current, which has been required in recent years, to have such a structure. In the case where the size is increased, special device structures involving electrode design, heat design, and the like are important in order for current to flow uniformly.

The light emitting section 3 can be formed on the surface of a III-V group compound semiconductor single crystal substrate such as gallium arsenide (GaAs), indium phosphide (InP), and gallium phosphide (GaP), or a silicon (Si) substrate. It is desirable to make the light emitting section 3 as a double hetero (abbreviation: DH) structure in which carriers that are responsible for radiative recombination can be confined as described above.

Moreover, it is desirable that the light emitting layer 2 is made to be a single quantum well structure (abbreviation: SQW) or a multi quantum well structure (abbreviation: MQW) in order to obtain emission that is excellent in monochromaticity.

It is possible to provide a buffer layer or the like, which buffers against lattice mismatch of the semiconductor layer 4 and the light emitting section 3, between the semiconductor layer 4 and the light emitting section 3. Furthermore, it is possible to provide a contact layer for reducing the contact resistance of the ohmic electrode, a current diffusion layer for diffusing device drive current over all the light emitting section evenly, and conversely a current blocking layer or a current narrowing layer, which restricts the area through which the device drive current flows.

In order to diffuse current in the light emitting section 3 uniformly, it is necessary to locate the ohmic electrode 8 evenly with respect to the light emitting section 3.

Preferably, the ohmic electrode 8 is formed such that it surrounds the outer perimeter of the light emitting section 3, and more preferably, it resembles the planar shaped profile of the light emitting section 3 and the planar shaped profile of the first electrode 6. Most preferably, the planar shape of the light emitting section 3 and the planar shape of the first electrode 6 are circular, and the planar shape of the ohmic electrode 8 is annular, encircling the light emitting section.

The material forming the ohmic electrode 8 can be for example, AuGe, AuSi, or the like for an N type semiconductor, or AuBe, AuZn, or the like for a P type semiconductor.

The penetrating electrodes 9 may be located such that the substrate 5 and the ohmic electrode 8 can be joined, and the shape, the quantity, and the like are not specifically limited.

The material is not particularly limited and may be a material that is conductive and can form metal vias joining the substrate 5 and the ohmic electrode 8.

More specifically, for example these can be formed using Cu, Au, Ni, solder, or the like.

In the present invention, for the semiconductor layer 4, it is preferable to use a semiconductor material that has low electrical resistance, and that can be formed into electrodes, and it is especially preferable that it is formed with a GaP layer that is stable chemically, and it is easy to form. It is possible to obtain excellent ohmic contact and reduce the operating voltage by the penetrating electrodes 9 being formed in the GaP layer, and the ohmic electrode 8 being formed on the GaP layer. Moreover, it is also possible to use a transparent conductive film such as ITO (Indium Tin Oxide).

In the present invention, it is preferable that the polarity of the first electrode 6 is n type, and the polarity of the second electrode 7 is p type. Using such a construction, it is possible to obtain the effect of high luminance. Since an n type semiconductor has lower electrical resistance and its current is more likely to diffuse, by making the first electrode 6 n type, current diffusion becomes good, and it is easy to achieve high luminance.

Furthermore, it is preferable to provide a contact layer (GaAs, GaInP, or the like) between the first electrode 6 and the light emitting section 3.

In the present invention, if the plane area of the light emitting diode 1 is defined as 100%, then if the plane area of the light emitting layer 2 and the plane area of the ohmic electrode 8 are S₁ and S₂ respectively, it is preferable to form a structure having the relationship of 60%<S₁<80%, and 5%<S₂<10%. By making such a shape, efficient emission over a large emission area with a small electrode area is possible, so that high brightness can be achieved. Moreover, since the ohmic electrode 8 absorbs light, it is preferable that the surface area is as small as possible. Furthermore, since the first electrode 6 blocks light from the light emitting layer 2, it is desirable to make the surface area of the first electrode 6 as small as possible within a range where wire bonding is possible.

### (Method for Manufacturing Light Emitting Diode)

Next, a method for manufacturing a light emitting diode 1 according to the first embodiment of the present invention will be described.

Firstly, a laminated structure of the light emitting section 3 is manufactured. For a method of forming the layered structure of the light emitting section 3, a metal organic chemical vapor deposition method (abbreviation: MOCVD), a molecular beam epitaxial (abbreviation: MBE) method, or a liquid phase epitaxial (abbreviation: LPE) method can be offered as examples.

In the present embodiment, a case where the light emitting diode is manufactured by joining the laminated epitaxial layer structure (epiwafer) provided on the GaAs substrate, and the GaP substrate is used as an example to describe the present invention specifically.

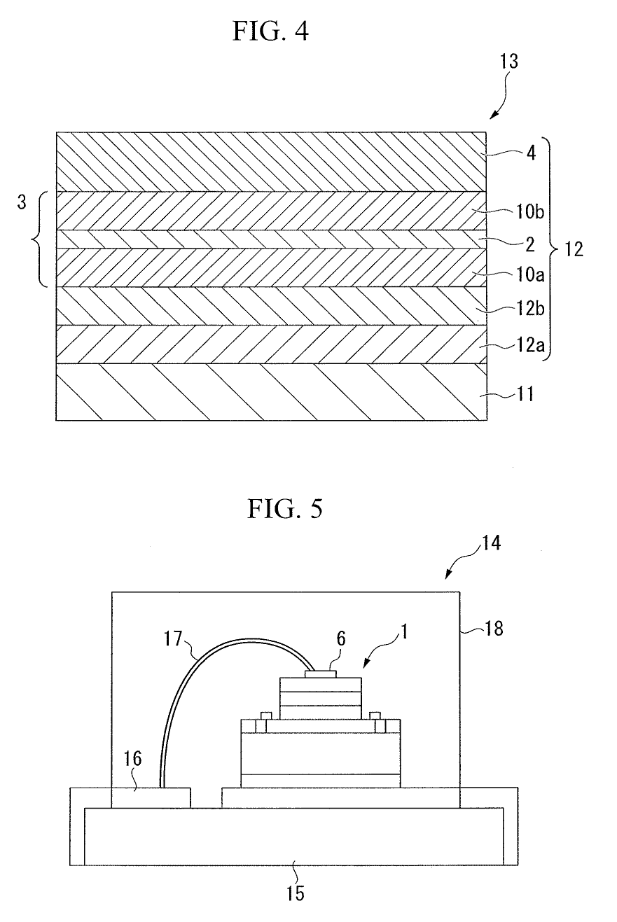

As shown in FIG. 4, the light emitting diode 1 is manufactured using for example, a laminated structure 13 of epitaxial layers having an epitaxial growth layer 12 laminated on a semiconductor substrate (a substrate for laminating epitaxial layers) 11 formed from a GaAs single crystal whose faces is inclined at 15° C. from a Si doped n type (100) surface. The laminated epitaxial growth layer 12 means: a buffer layer 12a formed from Si doped n type GaAs; a contact layer 12b formed from Si doped n type (Al_{0.5}Ga_{0.5})_{0.5}In_{0.5}P; a cladding layer 10a formed from Si doped n type (Al_{0.7}Ga_{0.3})_{0.5}In_{0.5}P; a light emitting layer 2 formed from 20 pairs of undoped (Al_{0.2}Ga_{0.8})_{0.5}In_{0.5}P/(Al_{0.7}Ga_{0.3})_{0.5}In_{0.5}P; a cladding layer 10b formed from Mg doped p type (Al_{0.7}Ga_{0.3})_{0.5}In_{0.5}P; and a Mg doped p type GaP layer (semiconductor layer 4).

In the present embodiment, each of the epitaxial growth layers 12 is laminated on the GaAs substrate (the substrate for laminating epitaxial layers) 11 using a low pressure MOCVD method in which trimethylaluminum ((CH₃)₃Al), trimethylgallium ((CH₃)₃Ga), and trimethylindium ((CH₃)₃In) are used for the raw materials of a III group constituent element in order to form the laminated structure of epitaxial layers 13. For the doping raw material of the Mg, biscyclopentadienyl (bis-(C₅H₅)₂Mg) can be used. For the doping raw material of the Si, disilane (Si₂H₆) can be used. Furthermore, for the raw material of a V group constituent element, phosphine (PH₃) or arsine (AsH₃) can be used. The semiconductor layer 4 formed from GaP is grown at 750° C. for example, and the other layers constituting the epitaxial growth layer 12 are grown at 730° C. for example.

The buffer layer 12a may have a carrier concentration of 2×10¹⁸ cm⁻³, and a thickness of 0.2 μm, for example. The contact layer 12b may be formed for example from (Al_{0.5}Ga_{0.5})_{0.5}In_{0.5}P, and the carrier concentration and the thickness may be 2×10¹⁸ cm⁻³ and 1.5 μm respectively. The cladding layer 10a may have a carrier concentration of 8×10¹⁷ cm⁻³, and a thickness of 1 μm, for example. The light emitting layer 2 may be undoped and have a thickness of 0.8 μm. The cladding layer 10b may have a carrier concentration of 2×10¹⁷ cm⁻³, and a thickness of 1 μm, for example. The semiconductor layer 4 may have a carrier concentration of 3×10¹⁸ cm⁻³, and a thickness of 9 μm, for example.

For the semiconductor layer 4, a range extending to 1 μm deep from the surface may be polished to a mirror finish, and the roughness of the surface may be 0.18 nm, for example. Here, the substrate 5 for adhering to the surface of the semiconductor layer 4, which has been polished to a mirror finish, is prepared. For the substrate 5 for adhering, as mentioned above, metals such as Cu, Al, and Ag are preferable. Si can also be used, and there are advantages in terms of ease of processing, and price.

The above-described substrate 5 and epitaxial laminated layer structure 13 are delivered to inside a joining device, and the inside of the device is exhausted to a vacuum of 3×10⁻⁵ Pa. Afterwards, in order to remove stains on the surfaces, an accelerated Ar beam is radiated on the surfaces of the substrate 5 and the epitaxial laminated layer structure 13. Afterwards, the two are joined at room temperature.

Next, the substrate 11 for laminating epitaxial layers and the buffer layer 12a are selectively removed from the joined structure using an ammonia system etchant.

An n type ohmic electrode (first electrode) 6 is formed on the surface of the contact layer 12b using a vacuum evaporation method such that the AuGe (Ge mass ratio 12%) is 0.15 μm, Ni is 0.05 μm, and Au is 1 μm.

Patterning is applied using a typical photolithographic method to form the first electrode 6. The planar shape of the first electrode 6 is preferably circular.

Next, the buffer layer 12b through to the cladding layer 10b of the epitaxial growth layer 12, which is in the region where the ohmic electrode 8 is formed, are removed selectively, exposing the semiconductor layer 4, and at the same time the light emitting section 3 is formed. The planar shape of the light emitting section 3 is preferably circular.

Then, holes are formed uniformly in the semiconductor layer 4 such that they surround the outer perimeter of the light emitting section 3, and metal vias are implanted in the holes to form the penetrating electrodes 9 such that they are joined to the substrate 5. The penetrating electrodes 9 may be columnar, with their material being Cu, their diameter being 20 μm, and their number being 4, placed at equal intervals such that the distance from the light emitting section 3 is 20 μm, for example.

Subsequently, the ohmic electrode 8 is formed on the surface of the semiconductor layer 4 such that it surrounds the outer perimeter of the light emitting section 3 and is joined to the penetrating electrodes 9. The ohmic electrode 8 may be formed using a vacuum evaporation method such that the AuBe is 0.2 μm, and Au is 1 μm, for example.

The shape of the ohmic electrode 8 is preferably similar to the planar shaped profile of the first electrode 6. It is most preferable that the planar shape of the first electrode 6 is circular, and the ohmic electrode 8 is annular.

The distance from the perimeter of the light emitting section 3 to the ohmic electrode 8 may be 10 μm, for example, and the width may be 10 μm, for example.

Afterwards, heat treatment is performed for 10 minutes at 450° C., for example, to form the alloyed, low resistance ohmic electrode 8. Then, a second electrode is formed on the bottom face of the substrate 5.

Afterwards, bonding pads may be formed using a vacuum evaporation method such that the first electrode 6 part has 1 μm of Au on it. Furthermore, a SiO₂ film with a thickness of 0.3 μm, for example, may be coated on the semiconductor layer 4 to form a protective film.

An LED chip (light emitting diode 1) manufactured in the above-described manner can be assembled in an LED lamp (light emitting diode lamp) 14 as shown schematically in FIG. 5. The LED lamp 14 is manufactured by fixing and mounting the LED chip 1 on a mounting substrate 15 using silver (Ag) paste, and after wire bonding the first electrode 6 and the n electrode terminal 16, which is provided on the surface of the mounting substrate 15, using gold wire 17, sealing using a typical epoxy resin 18.

As described above, the light emitting diode 1 of the present invention is provided with: the light emitting section 3 including the light emitting layer 2; the substrate 5 which is joined to the light emitting section 3 via the semiconductor layer 4; the first electrode 6 on the upper surface of the light emitting section 3; the second electrode 7 on the bottom surface of the substrate 5; and the ohmic electrode 8 around the outer perimeter of the light emitting section 3 on the semiconductor layer 4, and in the outer perimeter of the light emitting section 3, the ohmic electrode 8 and the substrate 5 are conductive, and the penetrating electrodes 9 are provided in the semiconductor layer 4, passing through the semiconductor layer 4 in the thickness direction. As a result, current flowing from the second electrode 7 can flow to the light emitting section 3 via the penetrating electrodes 9 and the ohmic electrode 8, passing through the substrate 5. Furthermore, since the ohmic electrode 8 is not at the adhesive interface of the substrate 5 and the semiconductor layer 4, the adhesive interface is not uneven, which makes the structure easy to bond, and it is also desirable in terms of processing, so that the characteristics and quality are also improved in a product such as an LED lamp using this light emitting diode 1.

### Second Embodiment

### Light Emitting Diode

Next is a description of a light emitting diode 1A according to a second embodiment of the present invention.

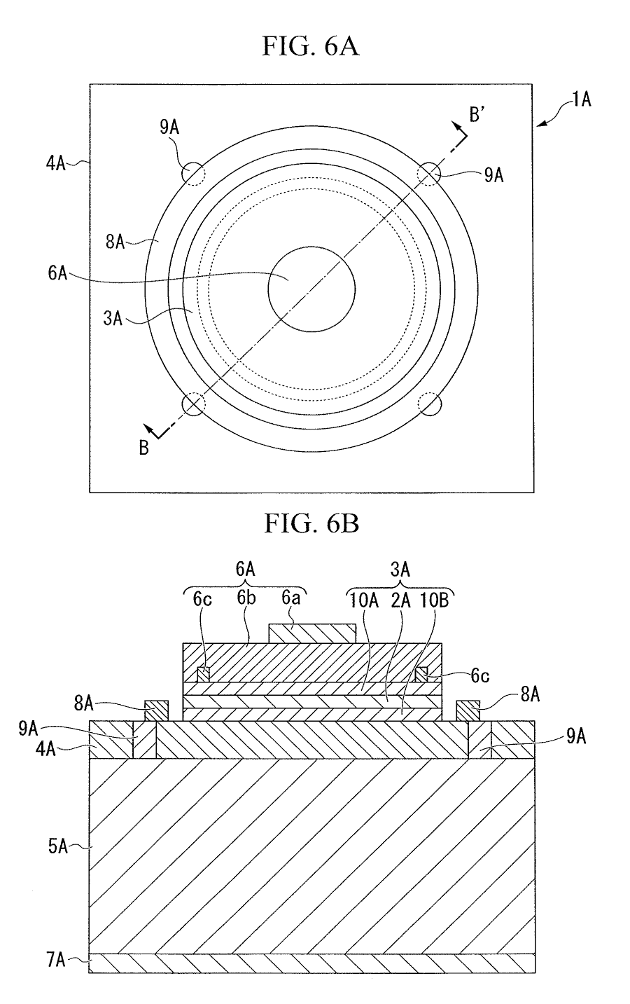

As shown in FIGS. 6A and 6B, similarly to the light emitting diode 1 of the first embodiment, the light emitting diode 1A is provided with: a light emitting section 3A having cladding layers 10A and 10B on the top and bottom of the light emitting layer 2A; a substrate 5A bonded to the light emitting section 3A via a semiconductor layer 4A; a first electrode 6A on an upper surface of the light emitting section 3A; a second electrode 7A on a bottom surface of the substrate 5A; and an ohmic electrode 8A around an outer perimeter of the light emitting section 3A on the semiconductor layer 4A, and in the outer perimeter of the light emitting section 3A, the ohmic electrode 8A and the substrate 5A are conductive, and penetrating electrodes 9A are provided in the semiconductor layer 4A, passing through the semiconductor layer 4A in the thickness direction.

The first electrode 6A is provided with a pedestal electrode 6a, a transparent conductive film layer 6b, which is formed from indium tin oxide (ITO), below the pedestal electrode 6a, and an n type ohmic electrode 6c inside of the transparent conductive film layer 6b along the inner perimeter of the transparent conductive film layer 6b.

The shape of the ohmic electrode 6c is preferably one that runs along the inner perimeter of the light emitting section 3A in order to diffuse current in the light emitting section 3A uniformly. The planar shape of the light emitting section 3A, the planar shape of the pedestal electrode 6a, and the planar shape of the transparent conductive film layer 6b are preferably similar, and most preferably they are circles formed as concentric circles.

The material forming the ohmic electrode 6c can be AuGe, AuSi, or the like for an N type semiconductor, or AuBe, AuZn, or the like for a P type semiconductor.

The other structures are almost the same as in the light emitting diode 1 according to the first embodiment.

By forming such shapes, the transparent conductive film plays the role of wiring that connects the pedestal electrode 6a and the ohmic electrode 6c, the degree of freedom of the layout, size, and shape of the ohmic electrode increases, and current diffusion is facilitated by optimum design, so that it is possible to obtain a light emitting diode 1A with low operating voltage. Moreover, for the pedestal electrode 6a, a material with a high reflection ratio can be selected, which reduces the absorption of light, enabling high luminance.

The shape of the ohmic electrode 6c is not limited to a ring as shown in FIG. 6B, and one in which small electrodes are spread in an island pattern may be used.

As described above, the light emitting diode 1A of the present invention is provided with: the light emitting section 3A including the light emitting layer 2A; the substrate 5A which is joined to the light emitting section 3A via the semiconductor layer 4A; the first electrode 6A on the upper surface of the light emitting section 3A; the second electrode 7A on the bottom surface of the substrate 5A; and the ohmic electrode 8A around the outer perimeter of the light emitting section 3A on the semiconductor layer 4A, and in the outer perimeter of the light emitting section 3A, the ohmic electrode 8A and the substrate 5A are conductive, and the penetrating electrodes 9A are provided in the semiconductor layer 4A, passing through the semiconductor layer 4A in the thickness direction. As a result, current flowing from the second electrode 7A can flow to the light emitting section 3A via the penetrating electrodes 9A and the ohmic electrode 8A, passing through the substrate 5A. Furthermore, since the ohmic electrode 8A is not at the adhesive interface of the substrate 5A and the semiconductor layer 4A, the adhesive interface is not uneven, which makes the structure easy to bond, and it is also desirable in terms of processing, so that the characteristics and quality are also improved in a product such as an LED lamp using this light emitting diode 1A.

Moreover, since there are provided the pedestal electrode layer 6a and the ITO layer 6b in the first electrode 6A, and the ohmic electrode layer 6c in the ITO layer 6b, it is possible to increase the degree of freedom in the design of the electrode, reduce the operating voltage of the light emitting diode 1A, and at the same time increase the light emission ratio.

### INDUSTRIAL APPLICABILITY

In the light emitting diode of the present invention, by the installation of penetrating electrodes, and the optimization of the shapes of the light emitting layer and the ohmic electrode, it is possible to provide a highly reliable light emitting diode with unconventionally high luminance and low operating voltage, and to use it for a range of display lamps and the like.

1. A light emitting diode comprising: a light emitting section which includes a light emitting layer; a substrate that is joined to said light emitting section via a semiconductor layer; a first electrode on an upper surface of said light emitting section; a second electrode on a bottom surface of said substrate; and an ohmic electrode around an outer perimeter of said light emitting section on said semiconductor layer, and in the outer perimeter of said light emitting section, said ohmic electrode and said substrate are conductive, and a penetrating electrode is provided in said semiconductor layer, passing through said semiconductor layer in a thickness direction.

2. A light emitting diode according to claim 1, wherein a planar shape of said light emitting layer is circular.

3. A light emitting diode according to claim 1, wherein said ohmic electrode surrounds an outer perimeter of said light emitting section.

4. A light emitting diode according to claim 1, wherein profiles of the planar shape of said light emitting section and said first electrode, and the planar shape of said ohmic electrode, are similar, and a distance between the outer perimeter of said first electrode and said ohmic electrode is constant.

5. A light emitting diode according to claim 1, wherein said light emitting section is provided with cladding layers made from semiconductor material on a top and bottom of said light emitting layer.

6. A light emitting diode according to claim 1, wherein said semiconductor layer has at least a layer made from GaP.

7. A light emitting diode according to claim 1, wherein said light emitting layer contains at least AlGaInP.

8. A light emitting diode according to claim 1, wherein said substrate is a transparent substrate made from any one of GaP, AlGaAs, and SiC.

9. A light emitting diode according to claim 1, wherein said substrate is a metal substrate containing at least any one of Al, Ag, Cu, and Au, or is made from a Si substrate having a reflective film formed with any one of Al, Ag, Cu, Au, and Pt.

10. A light emitting diode according to claim 1, wherein said first electrode has an ohmic electrode, a transparent conductive film layer, and a pedestal electrode.

11. A method for manufacturing a light emitting diode comprising: a step for forming a laminated epitaxial layer structure by stacking at least a contact layer, a first cladding layer, a light emitting layer, a second cladding layer, and a semiconductor layer, in order on a substrate for laminating epitaxial layers; a step for adhering a substrate on said semiconductor layer side of said light emitting section; a step for removing said substrate for laminating epitaxial layers from said laminated epitaxial layer structure to form a light emitting section; a step for providing a penetrating electrode in said semiconductor layer, passing through said semiconductor layer in a thickness direction, in an outer perimeter of said light emitting layer; a step for providing an ohmic electrode which is joined to said penetrating electrode, on said semiconductor layer, in an outer perimeter of said light emitting layer; and a step for providing a first electrode on an upper surface of said light emitting section and a second electrode on a bottom surface of said substrate.

12. A method for manufacturing a light emitting diode according to claim 11, that produces a light emitting diode comprising: a light emitting section which includes a light emitting layer; a substrate that is joined to said light emitting section via a semiconductor layer; a first electrode on an upper surface of said light emitting section; a second electrode on a bottom surface of said substrate; and an ohmic electrode around an outer perimeter of said light emitting section on said semiconductor layer, and in the outer perimeter of said light emitting section, said ohmic electrode and said substrate are conductive, and a penetrating electrode is provided in said semiconductor layer, passing through said semiconductor layer in a thickness direction.
